(19) United States
(12) Patent Application Publication
(10) Pub. No.: US 2025/0054887 A1
(43) Pub. Date: Feb. 13, 2025

(54) COPPER PAD METALLIZATION SYSTEMS AND RELATED METHODS

(71) Applicant: SEMICONDUCTOR COMPONENTS INDUSTRIES, LLC, Scottsdale, AZ (US)

(72) Inventors: Guy BRIZAR, Oosterzele (BE); Michael J. SEDDON, Gilbert, AZ (US)

(73) Assignee: SEMICONDUCTOR COMPONENTS INDUSTRIES, LLC, Scottsdale, AZ (US)

(21) Appl. No.: 18/446,127

(22) Filed: Aug. 8, 2023

(51) Int. Cl. H01L 23/00; H01L 21/768; H01L 23/532

(52) U.S. Cl. CPC H01L 24/05; H01L 21/76873; H01L 23/53238; H01L 24/45; H01L 2224/04042; H01L 2224/05624; H01L 2224/05647; H01L 2224/45124; H01L 2224/45147

(57) ABSTRACT

Implementations of a method of forming an interconnect may include forming a seed layer over a plurality of pads; patterning a layer of photoresist with a plurality of openings exposing the plurality of pads; forming a plurality of copper interconnects by electroplating each copper interconnect of the plurality of copper interconnects into each opening of the plurality of openings; removing the layer of photoresist; etching the seed layer; forming one or more layers on the plurality of copper interconnect; and patterning a layer of polyimide over the plurality of copper interconnects to form at least one opening over at least one copper interconnect of the plurality of copper interconnects.

### BACKGROUND

### 1. Technical Field

Aspects of this document relate generally to methods for forming electrical interconnects. More specific implementations involve electrical interconnects that include copper pads.

### 2. Background

Semiconductor packages have been devised that allow for routing of electrical signals from a semiconductor die to components of the package used to interface with a circuit board or motherboard to which the semiconductor package is attached. Semiconductor packages also have been developed that assist with protecting the semiconductor die from humidity, thermal conditions, or shock and vibration during operation and use.

### SUMMARY

Implementations of a method of forming an interconnect may include forming a seed layer over a plurality of pads; patterning a layer of photoresist with a plurality of openings exposing the plurality of pads; forming a plurality of copper interconnects by electroplating each copper interconnect of the plurality of copper interconnects into each opening of the plurality of openings; removing the layer of photoresist; etching the seed layer; forming one or more layers on the plurality of copper interconnect; and patterning a layer of polyimide over the plurality of copper interconnects to form at least one opening over at least one copper interconnect of the plurality of copper interconnects.

Implementations of a method of forming an interconnect may include one, all, or any of the following:

Forming the one or more layers on the at least one copper interconnect further may include electroless plating.

The one or more layers may include one of nickel, gold, palladium, or any combination thereof.

Forming the one or more layers on the at least one copper interconnect further may include sputtering.

The one or more layers include one of titanium, nickel, and gold; titanium, nickel, and palladium; or any combination thereof.

The seed layer may include titanium and tungsten or copper.

The method may include backgrinding a second side of a semiconductor substrate to thin the semiconductor substrate, the second side opposing a first side including the plurality of pads.

Implementations of a method of forming an interconnect may include forming a seed layer over a plurality of pads; patterning a layer of photoresist with a plurality of openings exposing the plurality of pads; forming a plurality of copper interconnects by electroplating each copper interconnect of the plurality of copper interconnects into each opening of the plurality of openings; applying an organic coating over each copper interconnect of the plurality of copper interconnects; removing the layer of photoresist; etching the seed layer; and patterning a layer of polyimide over the plurality of copper interconnects to form at least one opening over at least one copper interconnect of the plurality of copper interconnects.

Implementation of a method of forming an interconnect may include, one, all, or any of the following:

The method may include wirebonding to the at least one copper interconnect through the organic coating.

The method may include removing the organic coating after patterning the layer of polyimide and wirebonding to the at least one copper interconnect through the at least one opening.

Removing the organic coating further may include cleaning or etching.

The method may include reducing formation of copper oxide by applying the organic coating over each copper interconnect.

The layer of polyimide may directly contact the organic coating.

The at least one opening in the layer of polyimide over the at least one copper interconnect may expose only the copper of the at least one copper interconnect.

The at least one opening in the layer of polyimide over the at least one copper interconnect may expose only the organic coating over the at least one copper interconnect.

Implementations of a method of forming an interconnect may include forming a seed layer over a plurality of pads; patterning a layer of photoresist with a plurality of openings exposing the plurality of pads; forming a plurality of copper interconnects by electroplating each copper interconnect of the plurality of copper interconnects into each opening of the plurality of openings; applying a layer of aluminum over each copper interconnect of the plurality of copper interconnects; removing the layer of photoresist; etching the seed layer; and patterning a layer of polyimide over the plurality of copper interconnects to form at least one opening over at least one copper interconnect of the plurality of copper interconnects.

Implementations of a method of forming an interconnect may include one, all, or any of the following:

Applying a layer of aluminum further may include atomic layer depositing the layer of aluminum on each copper interconnect of the plurality of copper interconnects before removing the layer of photoresist.

Applying a layer of aluminum further may include atomic layer depositing the layer of aluminum on each copper interconnect of the plurality of copper interconnects after removing the layer of photoresist.

The method may include wirebonding to the at least one copper interconnect through the layer of aluminum.

The method may include reducing formation of copper oxide by applying the layer of aluminum over each copper interconnect.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a side cross sectional view of an implementation of a semiconductor substrate with pads formed thereon;

FIG. 2 is a side cross sectional view of the implementation of the semiconductor substrate of FIG. 1 following deposition of a seed layer;

FIG. 3 is a side cross sectional view of the implementation of the semiconductor substrate of FIG. 2 following formation of a photoresist pattern thereon;

FIG. 4 is a side cross sectional view of the implementation of the semiconductor substrate of FIG. 3 following electroplating of copper pads thereon;

FIG. 5 is a side cross sectional view of the implementation of the semiconductor substrate of FIG. 4 following formation of one or more layers over the exposed surface of the copper pad and removal of the photoresist;

FIG. 6 is a side cross sectional view of the implementation of the semiconductor substrate of FIG. 5 following etching/removal of the seed layer;

FIG. 7 is a side cross sectional view of the implementation of the semiconductor substrate of FIG. 6 following formation of a patterned polyimide layer over the copper pads;

FIG. 8 is a side cross sectional view of the implementation of the semiconductor substrate of FIG. 7 after formation of an additional layer on the exposed portion of the copper pad;

FIG. 9 is a side cross sectional view of another implementation of a semiconductor substrate with pads formed thereon;

FIG. 10 is a side cross sectional view of the implementation of the semiconductor substrate of FIG. 9 with a seed layer formed thereon;

FIG. 11 is a side cross sectional view of the implementation of the semiconductor substrate of FIG. 10 following formation of a photoresist pattern thereon;

FIG. 12 is a side cross sectional view of the implementation of the semiconductor substrate of FIG. 11 following electroplating of copper pads thereon;

FIG. 13 is a side cross sectional view of the implementation of the semiconductor substrate of FIG. 12 following removal of the photoresist and application of a layer to the top surfaces of the copper pads;

FIG. 14 is a side cross sectional view of the implementation of the semiconductor substrate of FIG. 13 following removal of the seed layer;

FIG. 15 is a side cross sectional view of the implementation of the semiconductor substrate of FIG. 14 following formation of a patterned polyimide layer over the copper pads and etching/removal of the layer over the top surface of the copper pad;

FIG. 16 is a side cross sectional view of the implementation of the semiconductor substrate of FIG. 13 following formation of a patterned polyimide layer over the copper pads;

FIG. 17 is a side cross sectional view of the implementation of the semiconductor substrate of FIG. 12 following removal of the photoresist layer and seed layer;

FIG. 18 is a side cross sectional view of the implementation of the semiconductor substrate of FIG. 17 following formation of a patterned polyimide layer over the copper pads; and

FIG. 19 is a side cross sectional view of the implementation of the semiconductor substrate of FIG. 18 following formation of a metal layer over the exposed portion of the copper pad.

### DESCRIPTION

This disclosure, its aspects and implementations, are not limited to the specific components, assembly procedures or method elements disclosed herein. Many additional components, assembly procedures and/or method elements known in the art consistent with the intended copper pad metallization systems will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such copper pad metallization systems, and implementing components and methods, consistent with the intended operation and methods.

In various semiconductor devices, logic circuits and power circuits can be combined. For example, in the case of a semiconductor device used to operate an automatic window opener in an automobile, the logic portion of the device senses the control signal indicating the window is to be raised or lowered and then activates the power portion (a metal oxide field effect transistor [MOSFET]) to transfer power to the motor for the specified period of time to allow the window to physically be raised or lowered. The voltage and power used by the logic portion of the device is typically much smaller in comparison with the voltage and power needed to operate the motor, so if the electrical interconnects used for the logic portion are used for the power portion of the device, the electrical interconnects can be damaged through overheat and/or excessive current load, even during the relatively short time that the high voltage/amperage is experienced during operation. In such systems, electrical interconnects adapted for higher power operation, such as thick copper interconnects like pads/bumps/pillars greater than 10 microns in height can be used to help the interconnects avoid damage during the high voltage transient load period. Similar structures in the form of metal lines greater than 10 microns in height are also used, and the principles disclosed herein can also be applied with metal lines. As wirebonding is often used to connect the source and drain pads of the MOSFET, for example, the ability to create reliable wirebonds with a wire bondable material of the thick copper interconnects is a design consideration when such combined logic and power circuits are combined in a semiconductor device.

In some process implementations, thick copper pads with a layer of gold and/or nickel on their upper surface are used. Since the sidewalls of the thick copper pads remain exposed in this process, the likelihood that particulate contamination can cause shorting between pads is increased as there is nothing present to fill the gaps between adjacent pads. In other process implementations, to assist with reducing the likelihood that particulate contamination can cause failures with the thick copper pads, the use of polyimide layers that fill in the space between the pads and cover the upper surface of the thick copper pillars is used in applications such as, by non-limiting example, automotive and other vehicle industries. Openings in the polyimide layer to expose the upper portion of the thick copper pillars are made into which the wirebonds are formed. In order to get the polyimide to adhere to the gold on the upper surface of the thick copper pads however, a film of palladium needs to be used as the top layer over the upper surface. The polyimide can also adhere to a layer of aluminum formed at the top layer over the upper surface of the thick copper pads, but does not adhere to the gold of the thick copper pads themselves.

Various methods for forming thick copper interconnect systems are disclosed in this document that utilize various layers of materials to which a polyimide material will adhere over the top surface of a thick copper pad/bump/pillar. These methods are merely exemplary, and combinations of these methods and materials disclosed herein may be employed in various system and method implementations. While in this document the term “pads” is used primarily to describe the methods and structures herein, it should be understood that the same principles may be applied with other metallization structures including bond pads, metal lines, or other large areas of metallization like dummy structures used to ensure local and wafer-level uniformity.

One of the challenges of forming wirebonds with pure copper pads is that the presence of copper oxide on the bond surface of the pads interferes with the formation of the intermetallic and alloy compounds that form a good mechanical and electrical connection between the bond wire and the copper pads. Thus, the ability to minimize and reduce the formation of copper oxide during the processing steps assists with the creation of good wirebonds. The various methods implementations disclosed herein show various approaches to reduce copper oxide formation on the bond surface/top surface of the copper pads disclosed herein.

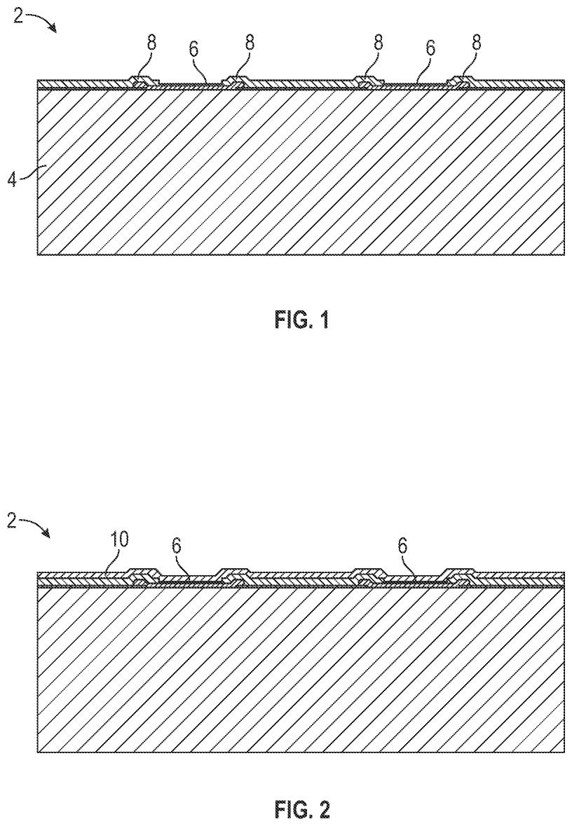

Referring to FIG. 1, a side cross sectional view of a semiconductor device 2 is illustrated which includes semiconductor substrate portion 4 on which is formed a plurality of pads 6. These pads 6 represent the outer layer of a stack of materials that are formed on/in the semiconductor substrate portion 4 which, for the sake of easier illustration, are not shown in FIG. 1 or the other figures, but are understood to be present as forming the active device(s) included in the semiconductor device 2. This stack of material helps forms structures such as, by non-limiting example, transistors, diodes, interconnects, traces, vias, insulating layers, and any other component of an active semiconductor device. Around each of the pads 6 is a layer of passivation material 8 which may be, by non-limiting example, silicon nitride, a polyimide, or another electrically insulating material. The particular material of the semiconductor substrate may be, by non-limiting example, silicon, silicon carbide, silicon on insulator, ruby, sapphire, gallium arsenide, gallium nitride, or any other semiconductor material type. The particular types of semiconductor devices that may employ the method implementations disclosed here may include, by non-limiting example, transistors, MOSFETs, insulated gate bipolar transistors (IGBTs), diodes, power devices, high electron mobility transistors (HEMTs), rectifiers, or any other power semiconductor device or other active semiconductor device type. While in FIG. 2 just two pads are illustrated, it is understood that this is merely for illustration convenience as the method implementations disclosed may be employed at the die-level or wafer-level portions of the fabrication process and many more pads than just two pads may be employed in various implementations.

Referring to FIG. 2, a side cross sectional view of the semiconductor device 2 of FIG. 1 is illustrated following formation of a seed layer 10 thereon for use in electroplating. The use of the seed layer 10 permits the formation of an electrical connection to the seed layer material covering each of the pads 6 during the electroplating operation. In various implementations, the seed layer 10 may be formed by sputtering. The seed layer 10 may include, by non-limiting example, a titanium and tungsten film, a copper film, any combination thereof, or another metal film type that permits electroplating of pure copper to the seed layer.

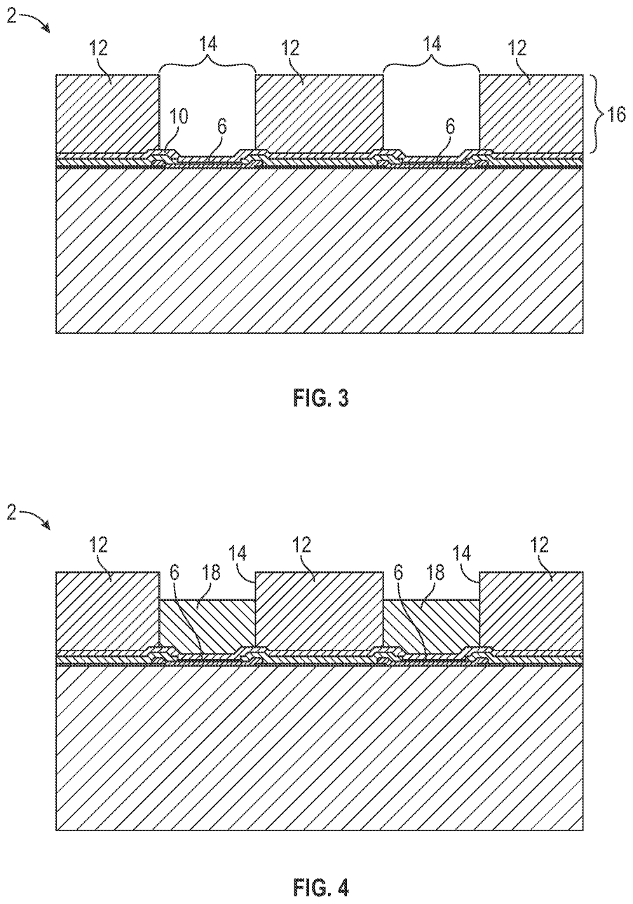

Following formation of the seed layer 10, referring to FIG. 3, a layer of photoresist 12 is applied which is then patterned. The application process for the photoresist 12 may include, by non-limiting example, spin coating, dispensing, stencil printing, squeegee application, or any other method for forming a uniform layer of material above the seed layer 10. The patterning process used may be specific to the particular type of photoresist employed. For example, where a positive photoresist is employed, the regions of the photoresist above the pads 6 are exposed with an electromagnetic radiation source through a mask to cause a corresponding reaction in the material of the photoresist that permits a developing solution to wash away the exposed regions. Where a negative photoresist is employed, the regions of the photoresist outside the pads are exposed to electromagnetic radiation causing a corresponding reaction in the material of the photoresist that prevents the developing solution from washing away the exposed regions. As illustrated in FIG. 3, the openings 14 in the photoresist 12 are larger than the size of the pads to allow the passivation material and any other under bump materials to assist in supporting the to-be-formed bump and help prevent issues like bump cracking later during operation. However, in other implementations, the size of the openings 14 may be the same as or substantially the same as the size of the pads. The height/thickness 16 of the photoresist 12 is set to be higher than or substantially the same as the height of the copper pads to be electroplated to help form the sidewalls and a flat upper/bonding surface for each of the copper pads.

Referring to FIG. 4, the semiconductor device 2 is illustrated following completion of the electroplating process that forms a copper pad/bump/pillar 18 within each of the openings 14 of the photoresist 12 which is mechanically and electrically connected with each corresponding pad 6. In this implementation, a pure copper pad has been formed, meaning that substantially all of the material of the pad is formed of just copper. In other implementations, however, a copper alloy could be electroplated, depending on the electrical or mechanical characteristics desired for the pads.

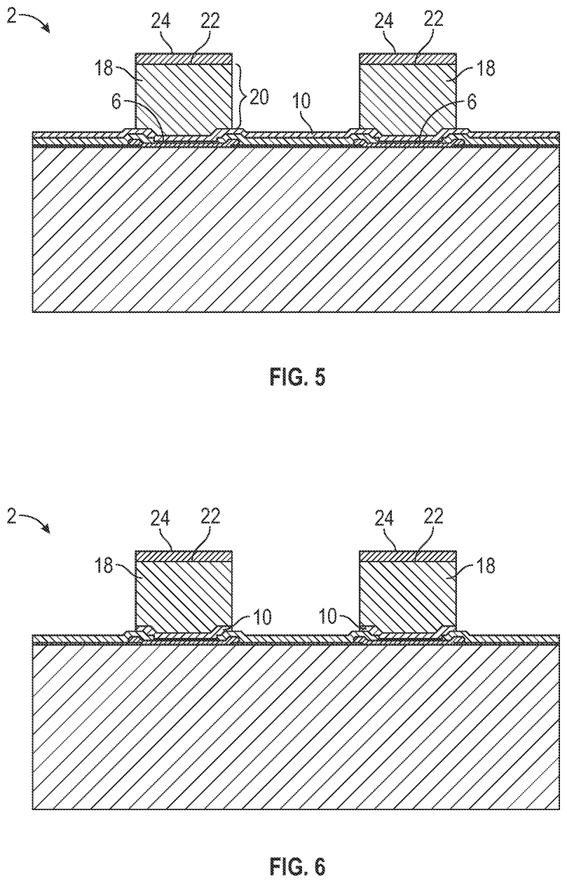

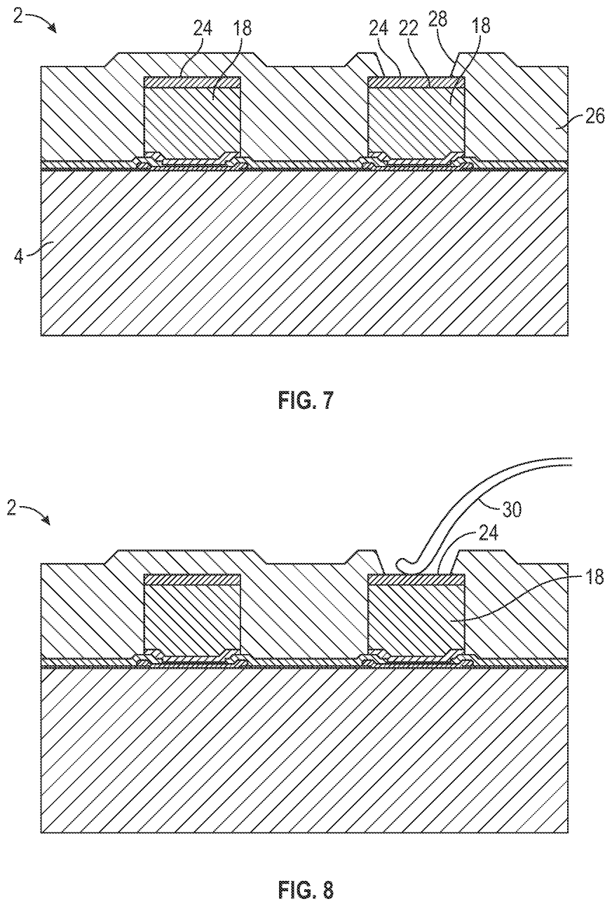

Referring to FIG. 5, the semiconductor device is illustrated following formation of one or more layers of material 24 on the top side/bonding surface 22 of each of the copper bumps 18 and after stripping/removal of the photoresist. In various method implementations, the one or more layers may be formed using electroless plating. Where the one or more layers are formed using electroless plating, the electroless plating may be carried out while the photoresist is still present around the copper pads 18 as illustrated in FIG. 4 after electroplating of the copper pads. In other implementations however, the electroless plating may take place after the photoresist has been removed and after removal of the seed layer 10 as in the structure illustrated in FIG. 6. While the one or more layers 24 are illustrated as being present on only the top of the copper pads 18 in FIG. 5 for ease of illustration, where the electroless plating takes place after removal of the photoresist and seed layer, it is understood that the material of the one or more layers may deposit on all exposed surface of each of the copper pads 18. Thus, if the one or more layers 24 are desired to be formed only on the bonding surface 22 of the copper pads 18, then the electroless plating would take place while the photoresist 12 is still in place as illustrated in FIG. 4.

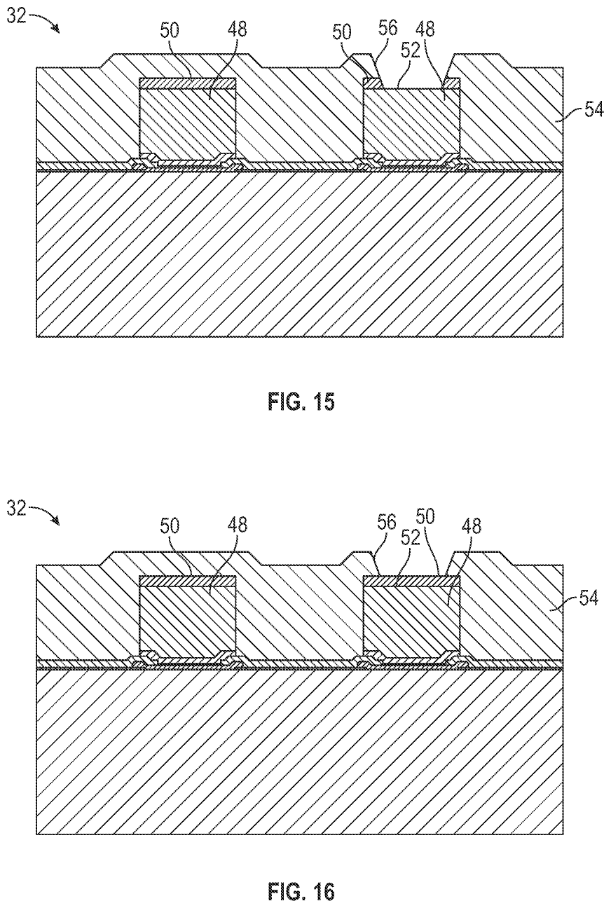

While the previous discussion discloses the use of electroless plating to form the one or more layers of material 24, in other method implementations, sputtering may be used to form the one or more layers of material 24. In such implementations, the sputtering takes place following the electroplating of the copper pads 18 while the photoresist 12 is still in place around the pads as illustrated in FIG. 14. The photoresist 12 is then stripped/removed as previously described, leaving the one or more layer of material 24 on the bond surface 22 of each of the copper pads 18 as illustrated in FIG. 5.

The materials used in the one or more layers of material 24 depend on the particular method of formation. Where electroless plating is employed, the material of the one or more layers may be nickel, gold, or palladium as a single layer in some implementations. In others, the material of the one or more layers may be nickel, gold, or palladium in two or more separate layers each formed through electroless plating. In yet other implementations, the material of the one or more layers may be any combination of nickel, gold, and/or palladium formed in a single layer or in multiple layers using electroless plating. Where the use of sputtering is employed, the material of the one or more layers may be, by non-limiting example, either titanium, nickel, and gold or titanium, nickel, and palladium formed in either a single layer or as separate layers.

The process of removing the photoresist may take place using various methods, including, by non-limiting example, solvent stripping, washing, ashing, etching, or any other method for removing polymer material. As illustrated, the as-plated copper pads 18 are then exposed and rise above the surface of the seed layer 10 at a desired height/thickness 20. As the seed layer 10 electrically shorts all of the copper pads 18 and all of the pads 6 together, it needs to be removed to electrically isolate all of the pads 6 from each other once again.

Referring to FIG. 6, the semiconductor device 2 of FIG. 5 is illustrated following removal of the seed layer material 10 from around the copper pads 18, leaving the seed layer 10 present only as an under bump material of each of the copper pads. The removal of the seed layer 10 may be carried out using etching in various method implementations. FIG. 6 also illustrates that, after the seed layer 10 has been removed, the one or more layers of material 24 remain formed onto the top surface/bonding surface 22 of each of the copper pads 18. In various implementations, the one or more layers of material 24 may be formed of a material that is not removed/etched by the process used to remove/etch the seed layer.

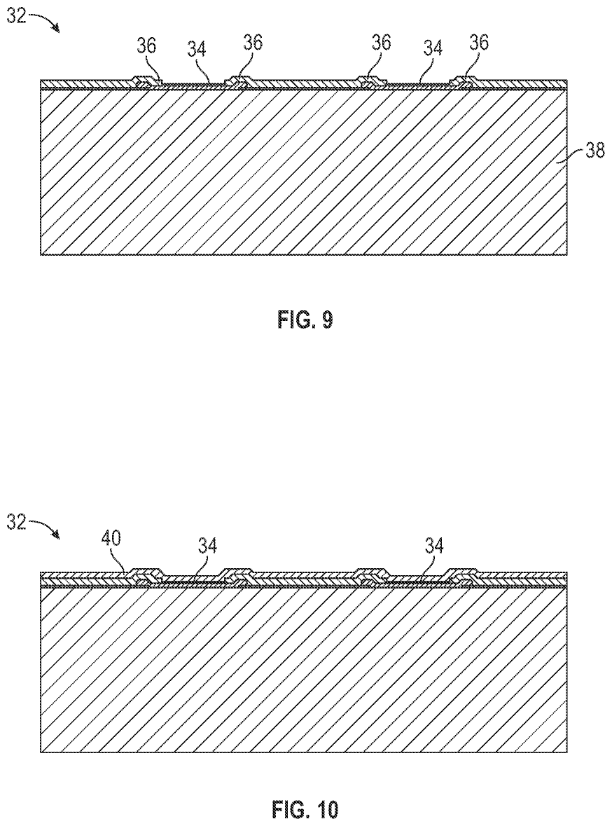

Referring to FIG. 7, the semiconductor device 2 is illustrated following application of a layer of polyimide 26 over the copper pads 18 and the patterning of opening 28 over the top surface/bonding surface 22. Note that not every copper pad 18 may have the top surface 22 with the one or more layers of material 24 exposed through an opening in the layer of polyimide 26. This may be because not all of the pads 6 are actually used for electrical interconnects and may be dummy pads used to preserve a certain amount of metal density at the pad layer to help improve processing uniformity or to help provide mechanical support/strength to the semiconductor device. The particular patterning method and process used to form the opening 28 in the polyimide 26 depends on the material of the polyimide and whether it is patterned photolithographically using positive or negative exposure processes like those previously described in this document. Because material types used in the one or more layers of material 24 are those previously described in this document, the polyimide 26 will adhere to the one or more layers 24 to form the opening 28 and allow for wirebonding into the opening 28. FIG. 8 illustrates the semiconductor device 2 following wire bonding of a bond wire 30 onto the one or more materials 24 and to the copper pad 18.

Prior to the wirebonding process, the semiconductor device 2 may have the semiconductor substrate portion thinned through, by non-limiting example, backgrinding, lapping, separating, polishing, or any other thinning process. Because of the use of the polyimide 26, the mechanical strength of the remaining portion of the semiconductor substrate portion may be improved to support a thinner die than could otherwise be produced without the presence of the polyimide 26 in the material stack. A wide variety of method variations may be constructed using the principles disclosed in this document.

Referring to FIG. 9, a second semiconductor device 32 is illustrated in a side cross sectional view that is similar in structure to the semiconductor device 2 of FIG. 1. The semiconductor device 32 includes pads 34 which are surrounded by passivation material 36. In the various method implementations, the material of the semiconductor substrate portion 38 of the semiconductor device 32 may be any disclosed in this document. In the various method implementations, the material of the passivation material 36 may also be any disclosed in this document. Also, the semiconductor device 32 may be any semiconductor device type disclosed in this document.

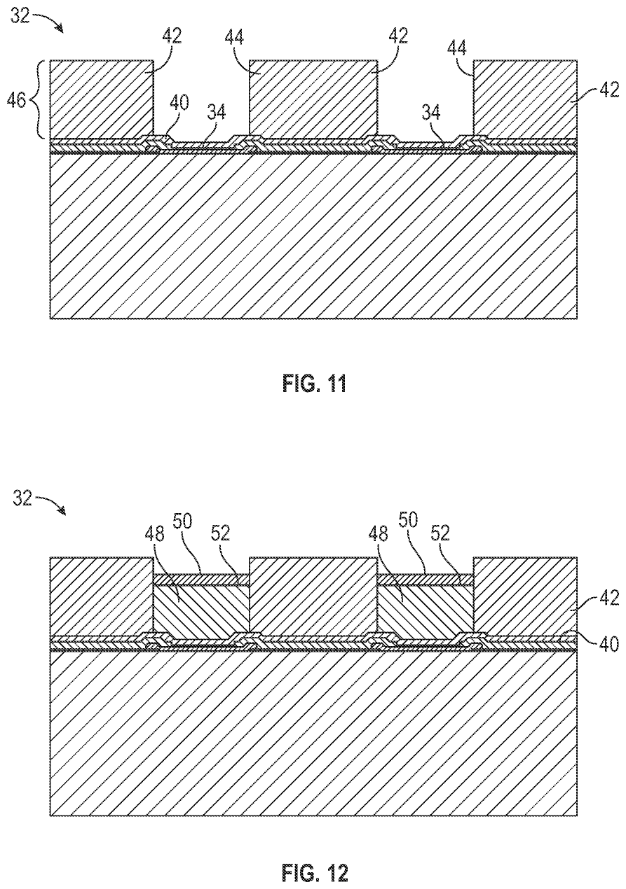

Referring to FIG. 10, the semiconductor device 32 is illustrated in a side cross sectional view following formation of a seed layer 40 over the pads 34. The material of the seed layer 40 may be any disclosed in this document used for seed layers for electroplating copper. FIG. 11 illustrates the semiconductor device 32 following formation of a patterned layer of photoresist 42 over the seed layer 40 with openings 44 over the pads 34. The material of the photoresist 42 may be any disclosed in this document and may be patterned using any of the patterning method implementations disclosed herein in various method implementations. The height/thickness 46 of the photoresist 42 above the seed layer 40 is again set at a level to achieve/support formation of copper pads at a desired thickness during electroplating.

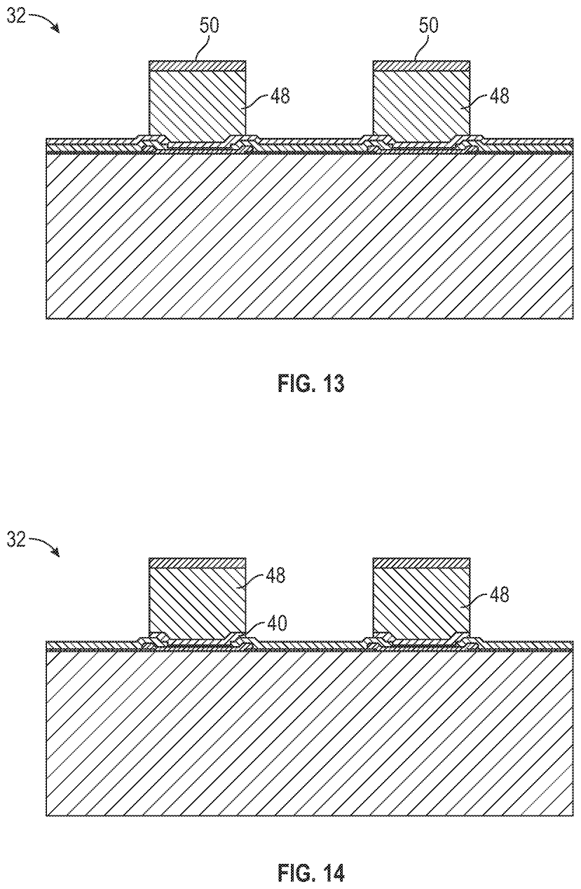

Referring to FIG. 12, the semiconductor device 32 is illustrated in a side cross sectional view following electroplating of copper pads 48. The electroplating process for forming the copper pads 48 and the material of the copper pads 48 may be any disclosed in this document. FIG. 12 also illustrates the semiconductor device 32 following the formation of one or more layers 50 over the top surface/bonding surface 52 of each of the copper pads 48. In various method implementations, the one or more layers 50 may include different materials formed and processed using corresponding methods. In a particular implementation, the one or more layers 50 is an organic coating that, when applied, prevents or substantially prevents reaction of oxygen with the newly plated copper of the copper pads 48, thus reducing the formation of copper oxide on the bonding surface 52. This organic coating is applied soon after the completion of the electroplating of the copper pads, thus helping to seal the bonding surface 52 of the copper pads 48 from reacting further with oxygen. Furthermore, the organic coating is a material to which a subsequently applied polyimide material will adhere. Also, the organic material in this implementation is one that a wirebond can be formed through during the wirebonding process and does not involve a cleaning or removal step.

In another implementation, the one or more layers 50 is an organic material that is thicker or more tightly bonded to the copper layer than the previously disclosed organic material of the previous method implementation. This organic material has the same ability to prevent further formation of copper oxide on the bonding surface 52 of the copper bumps 48, but needs to be removed/cleaned from the bonding surface 52 prior to the actual wirebonding using a cleaning step that will be discussed hereafter. In various implementations, the organic materials that may be employed in either method implementations may be organic solderability preservatives marketed by RBP Chemical Technology Inc. of Milwaukee, WI; MacDermid Alpha Electronics Solutions of Waterbury, CT; or Shikoku Chemicals Corporation of Marugame, Kagawa, Japan.

In another implementation, the one or more layers 50 is a layer of aluminum that is deposited on the bonding surface 52 that reacts with oxygen immediately to form aluminum oxide (alumina). In particular implementations, the layer of alumina is deposited using atomic layer deposition and may be between 1 to 5 atoms thick. In other implementations, however, other materials other aluminum may be used in the one or more layer 50, such as, by non-limiting example, titanium nitride, tantalum nitride, any combination thereof, or other material capable of being deposited using ALD. Such a layer is sufficiently thick to prevent diffusion of oxygen to the copper pad 48 and the formation of copper oxide but thin enough to be wire bonded through during the wirebonding process. In various method implementations where atomic layer deposition is employed, the aluminum is deposited while the photoresist 42 is present in the atomic layer deposition chamber leading to the structure illustrated in FIG. 12. In other implementations, however, the aluminum may be deposited after the photoresist 42 has been stripped from the seed layer 40 but before the seed layer 40 is etched. This may take place to avoid issues with outgassing or contamination of the process from the large thickness of photoresist present after the electroplating process has been completed. The aluminum adds the additional benefit in that a subsequently applied polyimide will adhere to the aluminum layer.

In other method implementations, a layer of aluminum between about 1 to about 4 microns is sputtered to form the one or more layers 50. In some implementations, the layer of aluminum may be about 2 microns thick. The layer of aluminum, when applied soon after plating of the copper, may assist with reducing copper oxide formation and also assist with adhesion of the polyimide subsequently formed over the copper pads.

Referring to FIG. 13, the semiconductor device 32 is illustrated in a side cross sectional view following removal of the photoresist. In the various method implementations, the photoresist may be removed using any of the methods disclosed in this document. In FIG. 13, the one or more layers 50 illustrated of the copper pads 48 may be either of the organic materials previously mentioned or the layer of aluminum deposited using atomic layer deposition previously discussed. FIG. 14 illustrates the semiconductor device 32 following removal of exposed portions of the seed layer 40 that are not part of the copper pads 48. The removal of the seed layer 40 may take place using any of the methods disclosed herein. In various methods, the particular removal method may also take into account the resistance of the material present of the one or more layers 50 to the particular removal method. In some implementations where the aluminum layer is present which was applied after removal of the photoresist, causing the aluminum to be deposited on the seed layer 40, a removal method that is capable of removing the aluminum either separately initially or in combination with the material of the seed layer 40 may be employed.

Referring to FIG. 15, the semiconductor substrate 32 is illustrated following application of a polyimide layer 54 over the copper pads 48 and patterning of that layer to form opening 56. FIG. 15 is a side cross sectional view following removal of the material of the one or more layers 50 that exposed through the opening 56. In this method implementation, the material of the one or more layers 50 is the organic material that needs to be removed/cleaned from the bonding surface 52 of the copper pads 48 prior to wirebonding. In this method implementation, because the organic material cannot be bonded through, it needs to be removed following the formation of the polyimide layer 54 while still providing adhesion to the bonding surface 52 of the copper pads 48 for the polyimide.

FIG. 16 illustrates an alternative structure that results from an alternative method implementation used where the aluminum layer or the organic coating forms the one or more layers 50 formed over the bonding surface 52. As in FIG. 15, a polyimide layer 54 has been formed over the copper pads 48 and patterned using any of the methods disclosed herein to form opening 56. However, the exposed material of the one or more layers 50 is not removed in this method implementation and so wire bonding takes place by bonding through either the organic coating or the aluminum layer formed by atomic layer deposition. In this way, the bond is not affected by copper oxide while a pure copper pad is still being bonded to while the polyimide layer 54 is still able to adhere to the bonding surface 52 of each of the copper pads 48.

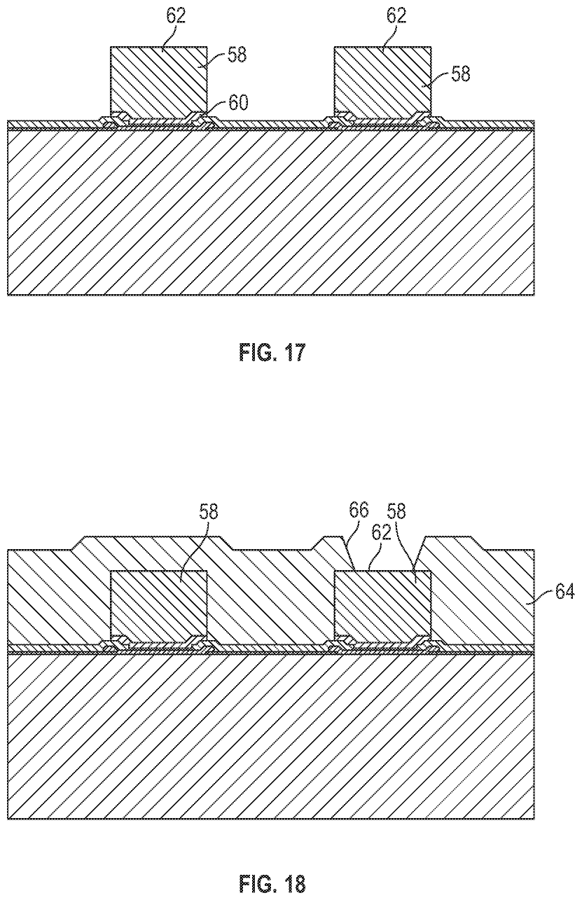

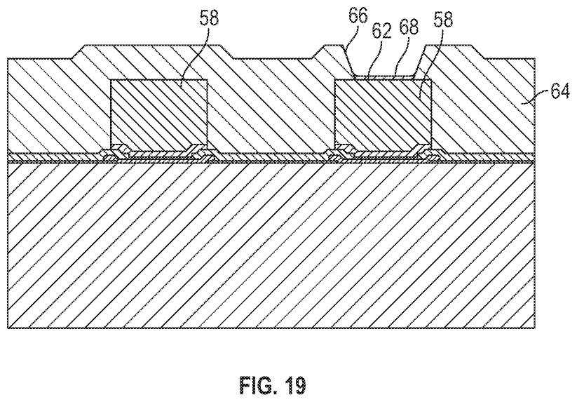

Referring to FIG. 17, copper pads 58 are illustrated after removal of the photoresist as illustrated in FIG. 12 and after etching of the seed layer 60. In this method implementation, however, no layer is applied over the top/bonding surface 62 of the copper pads following formation and prior to etching of the seed layer 60, leaving the top/bonding surface 62 as copper. FIG. 18 illustrates the copper pads 58 of FIG. 17 following formation of a polyimide layer 64 and formation of opening 66 to expose the top/bonding surface 62. In some method implementations, the polyimide layer 64 sufficiently sticks/bonds with the top/bonding surface 62 of the copper pads 58 so that no additional layer is applied to the top/bonding surface 62. In such implementations, the bonding is then carried out directly onto the top/bonding surface 62.

In other method implementations, like the one illustrated in FIG. 19, following forming the opening 66 in the polyimide 64, one or more layers 68 is formed over the top/bonding surface 62 of the copper pad 58. In some implementations, electroless plating may be used to form a layer of nickel, a layer of palladium, a layer of gold, or any combination thereof to form the one or more layers 68. In other implementations, sputtering may be used to apply titanium and aluminum (either as separate layers or a single layer) to form the one or more layers 68. In other implementations, sputtering may be used to apply titanium tungsten and aluminum (either as separate layers or a single layer) to form the one or more layers 68. In yet other implementations, atomic layer deposition may be employed to form the one or more layers 68 of any of the materials disclosed herein used for atomic layer deposition. As illustrated in FIG. 19, where sputtering is used to form the one or more layers 68, the material of the one or more layers 68 may rise up around the edges of the polyimide layer 64 of the opening 66.

A wide variety of possible combinations of electroless plated/sputtered/atomic layer deposition may be employed to form various layers on the top/bonding layer 62 of the copper pads 58 in various method implementations.

In places where the description above refers to particular implementations of copper pad metallization systems and implementing components, sub-components, methods and sub-methods, it should be readily apparent that a number of modifications may be made without departing from the spirit thereof and that these implementations, implementing components, sub-components, methods and sub-methods may be applied to other copper pad metallization systems.

What is claimed is:

1. A method of forming an interconnect comprising:
forming a seed layer over a plurality of pads;
patterning a layer of photoresist with a plurality of openings exposing the plurality of pads;
forming a plurality of copper interconnects by electroplating each copper interconnect of the plurality of copper interconnects into each opening of the plurality of openings;
removing the layer of photoresist;
etching the seed layer;
forming one or more layers on the plurality of copper interconnect; and
patterning a layer of polyimide over the plurality of copper interconnects to form at least one opening over at least one copper interconnect of the plurality of copper interconnects.

2. The method of claim 1, wherein forming the one or more layers on the at least one copper interconnect further comprises electroless plating.

3. The method of claim 2, wherein the one or more layers comprise one of nickel, gold, palladium, or any combination thereof.

4. The method of claim 1, wherein forming the one or more layers on the at least one copper interconnect further comprises sputtering.

5. The method of claim 4, wherein the one or more layers comprise one of titanium, nickel, and gold; titanium, nickel, and palladium; or any combination thereof.

6. The method of claim 1, wherein the seed layer comprises titanium and tungsten or copper.

7. The method of claim 1, further comprising backgrinding a second side of a semiconductor substrate to thin the semiconductor substrate, the second side opposing a first side comprising the plurality of pads.

8. A method of forming an interconnect comprising:
forming a seed layer over a plurality of pads;
patterning a layer of photoresist with a plurality of openings exposing the plurality of pads;
forming a plurality of copper interconnects by electroplating each copper interconnect of the plurality of copper interconnects into each opening of the plurality of openings;
applying an organic coating over each copper interconnect of the plurality of copper interconnects;
removing the layer of photoresist;
etching the seed layer; and
patterning a layer of polyimide over the plurality of copper interconnects to form at least one opening over at least one copper interconnect of the plurality of copper interconnects.

9. The method of claim 8, further comprising wirebonding to the at least one copper interconnect through the organic coating.

10. The method of claim 8, further comprising:
removing the organic coating after patterning the layer of polyimide; and
wirebonding to the at least one copper interconnect through the at least one opening.

11. The method of claim 10, wherein removing the organic coating further comprises cleaning or etching.

12. The method of claim 8, further comprising reducing formation of copper oxide by applying the organic coating over each copper interconnect.

13. The method of claim 8, wherein the layer of polyimide directly contacts the organic coating.

14. The method of claim 10, wherein the at least one opening in the layer of polyimide over the at least one copper interconnect exposes only the copper of the at least one copper interconnect.

15. The method of claim 9, wherein the at least one opening in the layer of polyimide over the at least one copper interconnect exposes only the organic coating over the at least one copper interconnect.

16. A method of forming an interconnect comprising:
forming a seed layer over a plurality of pads;
patterning a layer of photoresist with a plurality of openings exposing the plurality of pads;
forming a plurality of copper interconnects by electroplating each copper interconnect of the plurality of copper interconnects into each opening of the plurality of openings;
applying a layer of aluminum over each copper interconnect of the plurality of copper interconnects;
removing the layer of photoresist;
etching the seed layer; and
patterning a layer of polyimide over the plurality of copper interconnects to form at least one opening over at least one copper interconnect of the plurality of copper interconnects.

17. The method of claim 16, wherein applying a layer of aluminum further comprises atomic layer depositing the layer of aluminum on each copper interconnect of the plurality of copper interconnects before removing the layer of photoresist.

18. The method of claim 16, wherein applying a layer of aluminum further comprises atomic layer depositing the layer of aluminum on each copper interconnect of the plurality of copper interconnects after removing the layer of photoresist.

19. The method of claim 16, further comprising wirebonding to the at least one copper interconnect through the layer of aluminum.

20. The method of claim 16, further comprising reducing formation of copper oxide by applying the layer of aluminum over each copper interconnect.
